(19) United States
(12) Patent Application Publication
(10) Pub. No.: US 2009/0142706 A1
(43) Pub. Date: Jun. 4, 2009

(54) METHOD OF MANUFACTURING SEMICONDUCTOR DEVICE

(76) Inventors: Kazuyuki Masukawa, Kanagawa (JP); Koji Hashimoto, Kanagawa (JP); Kenji Kawano, Mie (JP); Yasunobu Kai, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/257,968

(22) Filed: Oct. 24, 2008

(30) Foreign Application Priority Data
Oct. 26, 2007 (JP) 2007-279343

(51) Int. Cl. G03F 7/20

(52) U.S. Cl. 430/319

(57) ABSTRACT

A method of manufacturing a semiconductor includes performing exposure using a first photomask having a pattern line in which hole patterns and assist patterns not transferred onto the semiconductor substrate are arrayed at an equal pitch on the mask, the pitch being converted a first pitch Pₕₒₗₑ on the substrate when the mask patterns are transferred on the substrate, and performing exposure using a second photomask having a pattern line in which wiring patterns are arrayed at an equal pitch on the mask, the pitch being converted a second pitch Pₗᵢₙₑ on the substrate when the mask patterns are transferred on the substrate, wherein m×Pₗᵢₙₑ=n×Pₕₒₗₑ and m,n(m>n) are integers.

### CROSS-REFERENCE TO RELATED APPLICATIONS

This application is based upon and claims the benefit of priority from the prior Japanese Patent Applications No. 2007-279343, filed on Oct. 26, 2007; the entire contents of which are incorporated herein by reference.

### BACKGROUND OF THE INVENTION

1. Field of the Invention

The present invention relates to a method of manufacturing a semiconductor device, and, more particularly, for example, to a method of exposing fine contact holes.

2. Description of the Related Art

In recent years, there is an increasing demand for small and large-capacity nonvolatile semiconductor storage devices. In particular, a NAND flash memory expected to be highly integrated and have a large capacity compared with a NOR flash memory in the past attracts attention. The line and space of wirings in the nonvolatile semiconductor storage devices such as the NAND flash memory is scaled as a fine resolution technology of photolithography advances.

In general, in a nonvolatile semiconductor memory, word lines and bit lines of memory cells are in contact with a memory cell array, and contacts for electrically connecting upper layer wirings and layer wirings need to be formed in a region drawn out to a peripheral circuit section. Formation of contact holes by photolithography is usually more difficult than formation of wirings (see, for example, JP-A 2004-348118 (KOKAI)).

### SUMMARY OF THE INVENTION

One aspect of the present invention is to provide a method of manufacturing a semiconductor device for transferring a pattern formed on a photomask onto a resist film on a semiconductor substrate using an exposing apparatus, the method comprising performing exposure using a first photomask having a pattern line in which hole patterns and assist patterns not transferred onto the semiconductor substrate, surrounded by a light shielding section or a semitransparent film, are arrayed at an equal pitch on the mask, the pitch being converted a first pitch on the substrate when the mask patterns are transferred on the substrate, and performing exposure using a second photomask having a pattern line in which wiring patterns surrounded by a light shielding section or a semitransparent film are arrayed at an equal pitch on the mask, the pitch being converted a second pitch on the substrate when the mask patterns are transferred on the substrate, wherein a value obtained by multiplying the second pitch with an integer m is equal to a value obtained by multiplying the first pitch with an integer n, and the integer m is larger than the integer n

### BRIEF DESCRIPTION OF THE DRAWINGS

FIG. 1 is a block diagram of a schematic configuration of a NAND flash memory according to a first embodiment of the present invention;

FIGS. 2A and 2B are a plan view and a sectional view of wiring drawing-out patterns in a sense amplifier region according to the first embodiment;

FIG. 3 is a schematic plan view of a photomask for contact hole formation according to the first embodiment;

FIGS. 4A and 4B are plan views for explaining illumination shapes used in a method of exposing contact holes according to the first embodiment;

FIG. 5 is a plan view for explaining hole patterns and assist patterns in the photomask for contact hole formation according to the first embodiment;

FIGS. 6A to 6C are diagrams for explaining, in comparison with a comparative example, a relation between focus depth and an exposure margin of patterns in the photomask according to the first embodiment;

FIG. 7 is a plan view of variations of a contact hole arrangement according to a second embodiment;

FIG. 8 is a schematic plan view of a photomask for contact hole formation according to a first method of the comparative example;

FIG. 9 is a plan view for explaining an arrangement of hole patterns and assist patterns in the photomask for contact hole formation according to the first method of the comparative example;

FIG. 10 is a schematic plan view of a photomask for contact hole formation according to a second method of the comparative example; and

FIG. 11 is a plan view for explaining a contact hole arrangement according to the second method of the comparative example.

### DETAILED DESCRIPTION OF THE INVENTION

Exemplary embodiments of the present invention are explained in detail below.

Before explaining the embodiments, a comparative example is explained.

Two methods described below are conceivable as a contact hole forming method for extracting a signal from wirings having a fine pitch (in the following explanation, the fine pitch means a minimum line and space (L/S) determined by a photolithography resolution technology). Dimensions of a photomask explained in this comparative example and embodiments explained below are represented by values being converted into dimensions when the photomask is transferred onto a resist film on a semiconductor substrate.

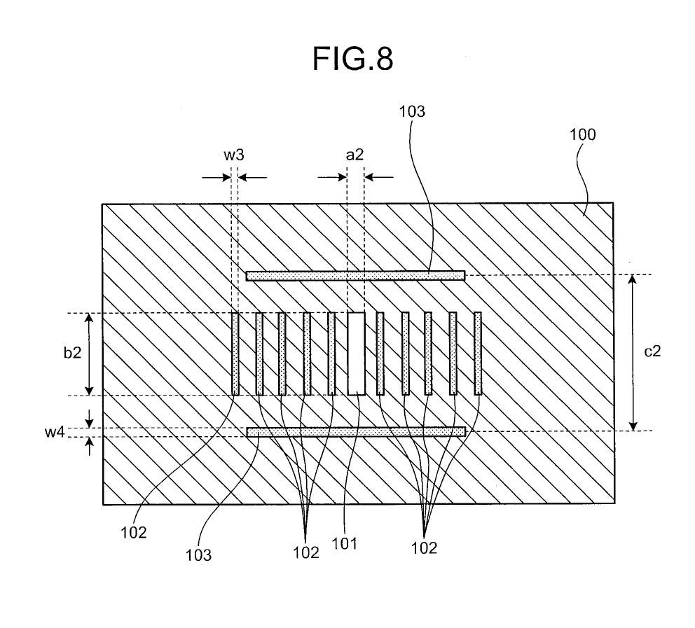

A first method is a method of performing exposure using an isolated hole pattern shown in FIG. 8. FIG. 8 is a schematic plan view of a photomask 100 for contact hole formation according to a first method of the comparative example. In the photomask 100, for example, a plurality of assist patterns (Sub Resolution Assist Features (SRAF)) 102 having the width w3=33 nm and resolution equal to or lower than a resolution limit are arranged at an equal pitch in a width direction of a hole pattern 101 of a rectangular shape having the width a2=86 nm and the length b2=402 nm. In FIG. 8, five assist patterns 102 are arranged on each of both sides of the hole pattern 101.

Assist patterns 103 having the width w4=26 nm and resolution equal to or lower than the resolution limit are arranged a space c2=726 nm apart from each other in a direction orthogonal to an array direction of the hole pattern 101 and the assist patterns 102. The isolated hole pattern 101, the assist patterns 102, and the assist patterns 103 are formed to be surrounded by a semitransparent film formed on a transparent substrate. Alternatively, the isolated hole pattern 101, the assist patterns 102, and the assist patterns 103 can be formed to be surrounded by a light shielding film formed on the transparent substrate.

Contacts formed in a semiconductor device such as a nonvolatile semiconductor memory need to have small width and small dimensional fluctuation to prevent short-circuit with fine-pitch wirings adjacent thereto. It is technically difficult to form the contacts. To meet this request, assist patterns having resolution equal to or lower than the resolution limit are arranged around a hole pattern on a photomask. This makes it possible to densely form contact holes having small width and small dimensional fluctuation.

In the photomask 100 shown in FIG. 8, the assist patterns 102 and the assist patterns 103 having resolution equal to or lower than the resolution limit are arranged around the isolated hole pattern 101. Therefore, it is possible to improve resolution in a contact hole width direction and form contact holes having smaller width. However, formation of contact holes by photolithography is usually more difficult than formation of periodically-arrayed wirings. When the contact holes are actually transferred onto a resist film on a semiconductor substrate, restrictions described below occur.

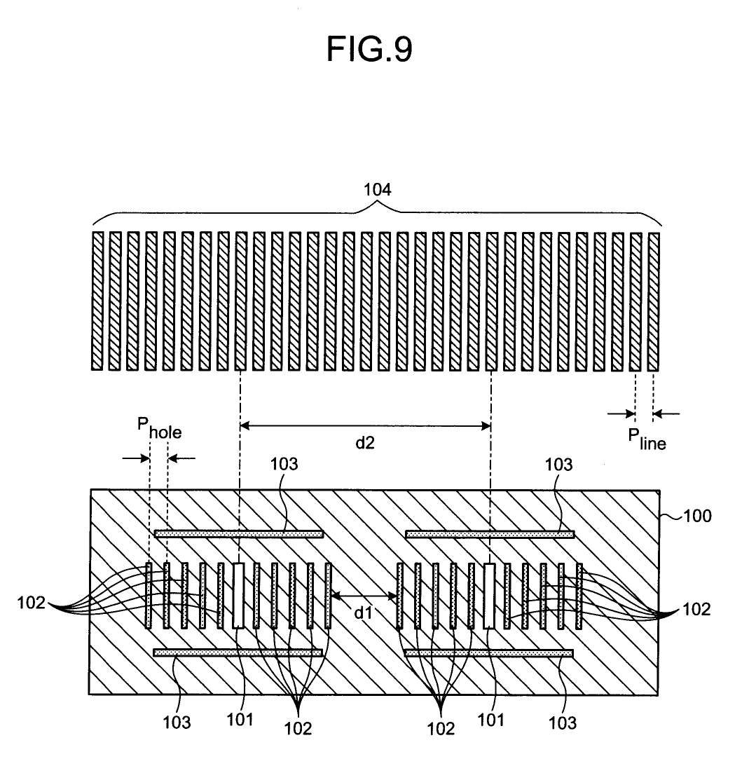

FIG. 9 is a plan view for explaining a positional relation between fine-pitch wirings 104 to be transferred onto the semiconductor substrate and the photomask 100 on which a pair of the isolated hole patterns 101 are arranged to be adjacent to each other. As described above, dimensions of the photomask are values converted into dimensions when the photomask is transferred onto the resist film on the semiconductor substrate. Therefore, for convenience of explanation, a positional relation between fine-pitch wirings to be transferred onto the resist film on the semiconductor substrate and mask patterns arrayed on the photomask for contact hole formation is discussed below.

Formation of contact holes by photolithography is more difficult than formation of periodically-arrayed wirings. Therefore, as shown in FIG. 9, a pitch Pₕₒₗₑ among the isolated hole patterns 101 and the assist patterns 102 needs to be wider than a pitch Pₗᵢₙₑ among the wirings 104. Moreover, a distance d2 between the isolated hole patterns 101 needs to be increased to increase a distance between the assist patterns 102 adjacent to each other located at ends of the isolated hole patterns 101 to a distance dl for preventing the assist patterns 102 from affecting optical images thereof each other.

On the other hand, if the number of the assist patterns 102 can be reduced, a distance between the isolated hole patterns 101 can be reduced. However, in this case, an exposure margin falls and dimensional fluctuation of contact holes to be transferred onto the resist film on the semiconductor substrate increases. Therefore, in the first method, it is difficult to simply reduce the number of assist patterns 102 around the isolated hole patterns 101.

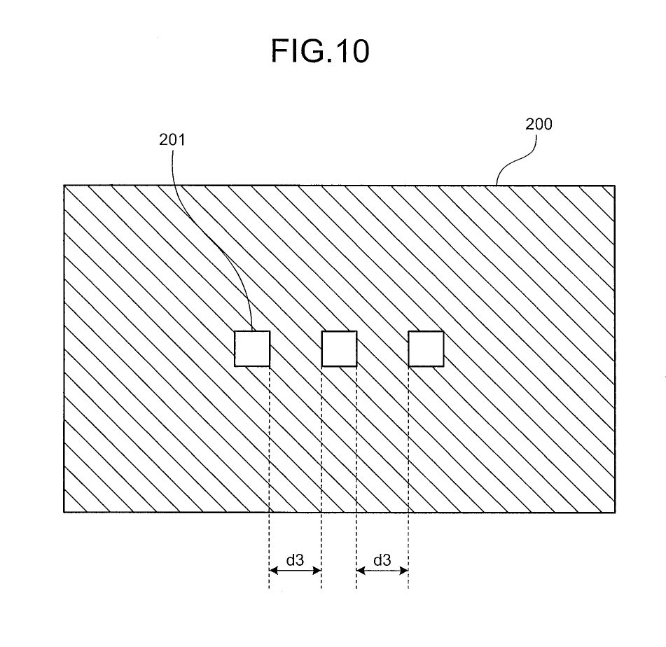

A second method is a method of performing exposure without arranging any assist patterns around isolated hole patterns. FIG. 10 is a schematic plan view of a photomask 200 for contact hole formation according to the second method of the comparative example. In the photomask 200, hole patterns 201 of a square shape having the length of each side of 137 nm are arranged a distance d3=163 nm apart from one another in one direct. In the second method, unlike the first method, assist patterns are not arranged around the hole patterns 201. This makes it possible to reduce an arrangement space between hole patterns 201 adjacent to each other.

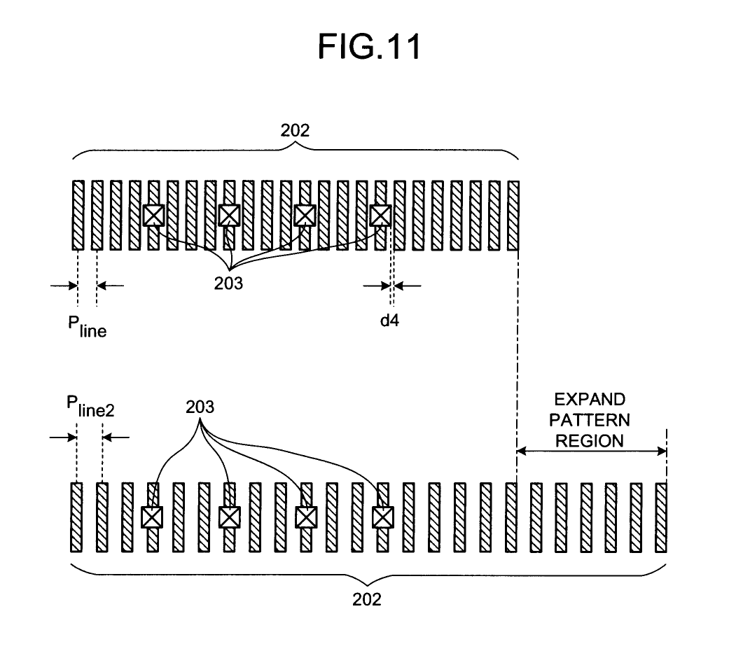

However, as described above, resolution in a contact width direction is lower when assist patterns are not arranged than when assist patterns are arranged. Therefore, as shown in FIG. 11, it is difficult to secure a distance d4 between wirings 202 formed at a fine pitch Pₗᵢₙₑ and contact holes 203 formed by exposure using the hole patterns 201. Therefore, as shown in FIG. 11, it is necessary to increase a pitch of the wirings 202, which are desired to be formed at the fine pitch, to Pₗᵢₙₑ₂ larger than Pₗᵢₙₑ. Moreover, as a result of increasing the pitch, a pattern region for drawing out the wirings is expanded.

A NAND flash memory is explained below as an example of a semiconductor device according to a first embodiment of the present invention. The present invention is not limitedly applied to the NAND flash memory and can naturally be applied to other semiconductor devices.

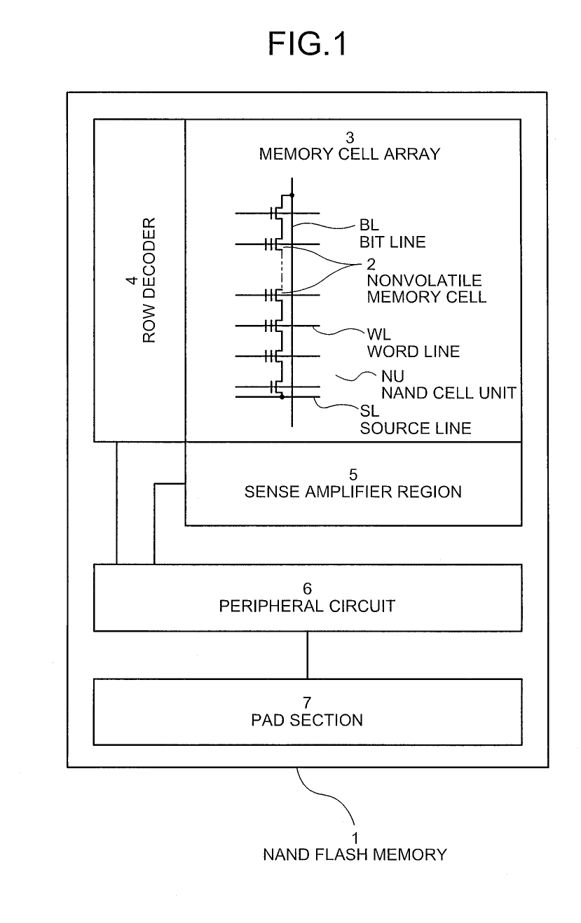

FIG. 1 is a block diagram of a schematic configuration of a NAND flash memory 1 according to this embodiment. The NAND flash memory 1 according to this embodiment includes a memory cell array 3 in which nonvolatile memory cells 2 are arrayed in a matrix shape, a row decoder 4, a sense amplifier region 5, a peripheral circuit 6, and a pad section 7.

The memory cell array 3 is configured by arraying a plurality of NAND cell units NU to which the nonvolatile memory cells 2 are serially connected. The nonvolatile memory cells 2 have floating gate electrodes formed on a semiconductor substrate via a tunnel insulating film and control gate electrodes stacked on the floating gate electrodes via an inter-gate insulating film.

One ends of the NAND cell units NU are connected to bit lines BL via selection gate transistors and the other ends thereof are connected to common source lines SL via the selection gate transistors. The control gate electrodes of the nonvolatile memory cells 2 in an identical row extend in a memory cell column direction to be connected in common and form word lines WL. The control electrodes of the selection gate transistors extend in the memory cell column direction to be connected in common and form selection gate lines SGL.

The row decoder 4 is arranged on one end side of the world lines WL, and performs selective driving for the word lines WL and the selection gate lines SGL according to an address input via the pad section 7 and the peripheral circuit 6. The sense amplifier region 5 is arranged on one end side or both end sides of the bit lines BL and includes a plurality of sense amplifiers SA served for writing and readout of data.

In the memory cell array 3, in general, the word lines WL or the bit lines BL are formed at a fine pitch. For example, a line and space of the word lines WL adjacent to each other and a line and space of the bit lines BL adjacent to each other are 42 nm/42 nm (L/S).

A wiring layout in the sense amplifier region 5 of the NAND flash memory 1 according to this embodiment is explained below.

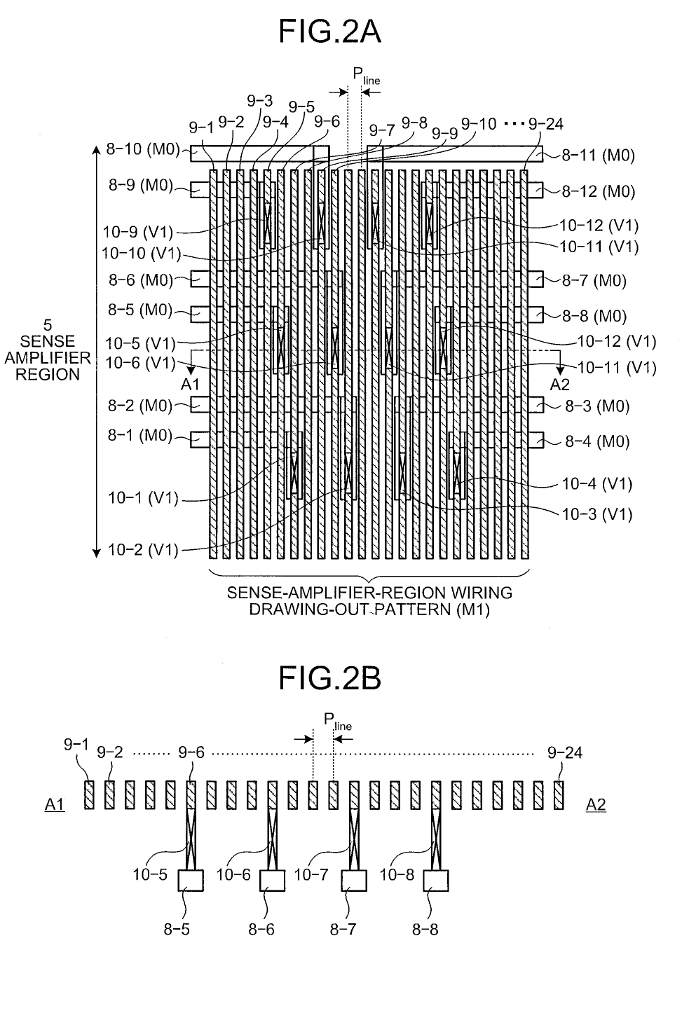

FIG. 2A is a plan view of a wiring drawing-out section in the sense amplifier region 5 of the NAND flash memory 1 shown in FIG. 1. In FIG. 2A, a first wiring layer M0 in which drawn-out wirings 8-1, 8-2, . . . , and 8-12 (which may be generally referred to as drawn-out wirings 8 below), a second wiring layer M1 in which sense-amplifier-region wiring drawing-out patterns 9-1, 9-2, . . . , and 9-24 (which may be generally referred to as wiring patterns 9 below), and a contact layer on first wiring layer V1 in which contacts 10-1, 10-2, . . . , and 10-12 (which may be generally referred to as contacts 10 below) between the drawing-out wirings 8 and the wiring patterns 9 are formed are shown. Wiring layers below the first wiring layer M0 and wiring layers above the second wiring layer M1 are not shown in the figure.

FIG. 2B is a sectional view of a sectional structure in an A1-A2 direction of the wiring drawing-out section shown in FIG. 2A. As shown in FIG. 2B, the drawn-out wirings 8-5, 8-6, 8-7, and 8-8 formed in the first wiring layer M0 are larger in width than the wiring pattern 9 and are apart from the contacts 10 adjacent thereto. Therefore, dimensional fluctuation of the drawn-out wirings 8 may be large and it is easy to form the wirings. The drawn-out wrings 8 are drawn around as required and connected to the sense amplifier circuit SA.

The wiring patterns 9 formed in the second wiring layer M1 are formed at the fine pitch Pₗᵢₙₑ in the same manner as the word lines WL or the bit lines BL in the memory cell array 3. The wiring patterns 9 are formed at a pitch of, for example, 42 nm/42 nm (L/S).

The contacts 10 formed in the first contact layer on wiring layer V1 have width substantially the same as that of the sense-amplifier-region wiring drawing-out pattern 9. Center lines of the wiring patterns 9 and the contacts 10 coincide with each other. The contacts 10 are arranged at an interval (4×Pₗᵢₙₑ) four times as large as the pitch Pₗᵢₙₑ among the wiring patterns 9 in a contact column formed by the contacts 10 in an identical row. One contact 10 corresponds to one wiring pattern 9. Contact columns adjacent to each other are arranged at an interval corresponding to a predetermined area necessary for drawing around the drawn-out wirings 8.

In the NAND flash memory 1 according to this embodiment, the wiring patterns 9 are formed at the fine pitch in the same manner as the word lines WL or the bit lines BL in the memory cell array 3. Therefore, an area of the drawing-out pattern region can be reduced. This makes it possible to reduce a chip area compared with that in the past.

When the wiring patterns 9 are formed at the fine pitch in the same manner as the word lines WL or the bit lines BL in the memory cell array 3, if formation positions of the contacts 10 shift even a little, it is likely that the contacts 10 are short-circuited with the wiring patterns 9 adjacent thereto. For example, when a formation position of the contact 10-5 formed right below the sense-amplifier-region wiring drawing-out pattern 9-6 shifts, it is highly likely that the contact 10-5 is short-circuited with the sense-amplifier-region wiring drawing-out pattern 9-5 or the sense-amplifier-region wiring drawing-out pattern 9-7.

In this embodiment, a method of exposing fine contact holes used for extracting a signal from the fine-pitch wirings in the sense amplifier region 5 is explained below.

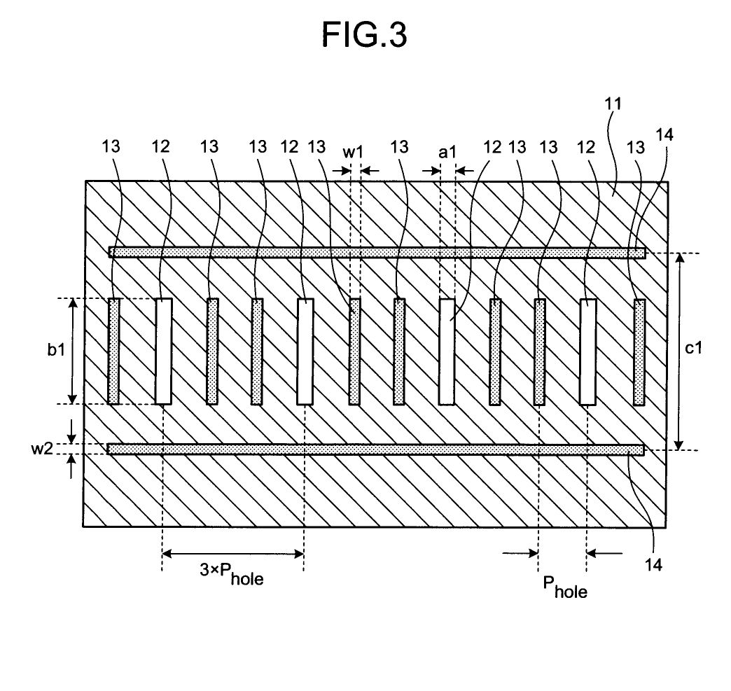

FIG. 3 is a schematic plan view of a photomask 11 for contact hole formation according to this embodiment. As shown in FIG. 3, a plurality of hole patterns 12 of a rectangular shape having the width a1=42 nm and the length b1=220 nm are arranged in a width direction. Two assist patterns 13 having resolution equal to or lower than a resolution limit are arranged between the hole patterns 12 adjacent to each other. The size of the assist pattern 13 are set to, for example, width w1=29 nm and length b1=220 nm. The hole patterns 12 and the assist patterns 13 are arranged at an equal pitch. A pitch Pₕₒₗₑ among the hole patterns 12 and the assist patterns 13 is set to 56 nm. Therefore, the hole patterns 12 are arranged at a pitch (3×Pₕₒₗₑ) three times as large as the pitch Pₕₒₗₑ among the hole patterns 12 and the assist patterns 13.

Assist patterns 14 having the width w2=29 nm and resolution equal to or lower than the resolution limit are arranged a space c1=1036 nm apart from each other in a direction orthogonal to an array direction of the hole patterns 12 and the assist patterns 13. The hole patterns 12, the assist patterns 13, and the assist patterns 14 are formed to be surrounded by a semitransparent film formed on a transparent substrate. Alternatively, the hole patterns 12, the assist patterns 13, and the assist patterns 14 can be formed to be surrounded by a light shielding film formed on the transparent substrate.

The following relational expression (1) holds among a wiring pattern pitch P, exposure wavelength λ, a numerical aperture NA of illumination of an exposing apparatus, and an opening position σ.

NA=λ/(2×P×σ) (1)

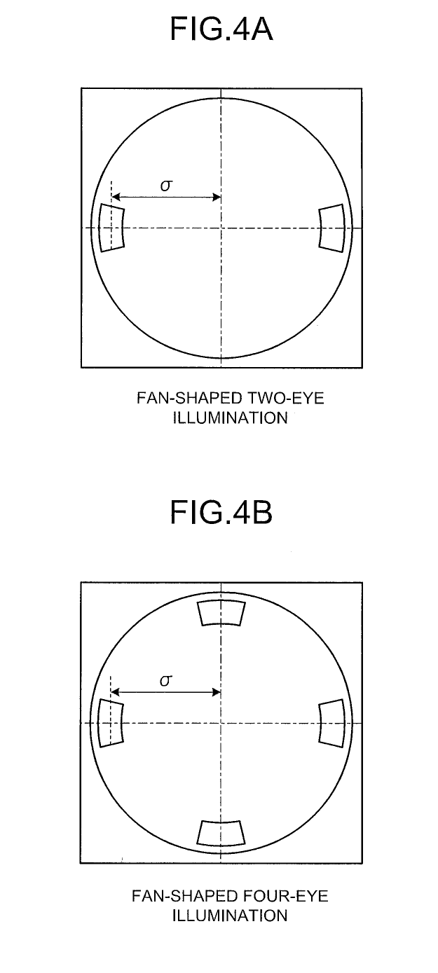

As an illumination shape, for example, fan-shaped two-eye illumination shown in FIG. 4A and fan-shaped four-eye illumination shown in FIG. 4B are conceivable. FIGS. 4A and 4B are schematic plan views of an example of the illumination shape used in the method of exposing contact holes according to this embodiment.

It is seen from the relational expression (1) that it is possible to form contact holes by an exposing apparatus having a lower numerical aperture with respect to a wiring pattern by increasing the pitch Pₕₒₗₑ among the hole patterns and the assist patterns compared with the pitch Pₗᵢₙₑ among equivalent wiring (line) patterns. The magnitude of the numerical aperture and a price of an exposing apparatus that enables the numerical aperture are proportional to each other. Therefore, it is possible to substantially reduce cost by reducing a necessary numerical aperture.

In this embodiment, for example, the wiring patterns 9 in the second wiring layer M1 are formed at the fine pitch Pₗᵢₙₑ of 42 nm/42 nm (L/S) by using an ArF immersion exposing apparatus having the numerical aperture NA=1.3. The contact holes 10 formed in the first contact layer on wiring layer V1 are formed by using an ArF exposing apparatus having the numerical aperture NA=1.0. A value of the numerical aperture described in this embodiment is only an example. It only has to be assumed that a numerical aperture of an exposing apparatus for contact hole formation is lower than a numerical aperture of an exposing apparatus used for wiring pattern formation.

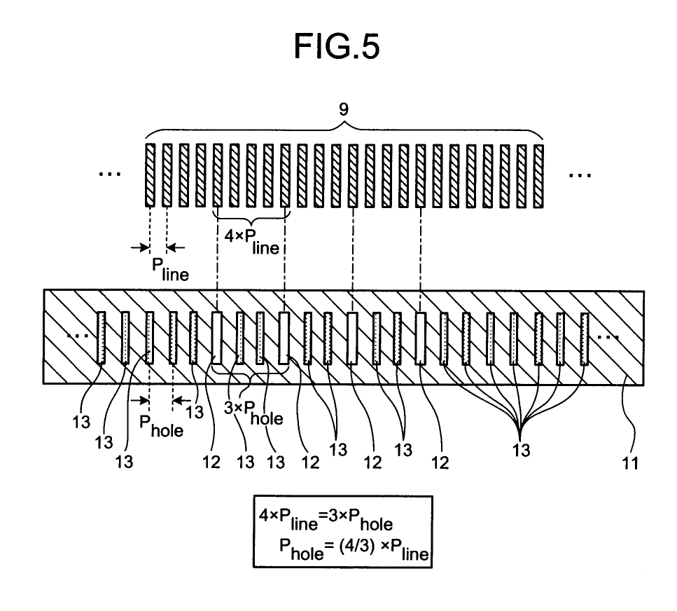

FIG. 5 is a plan view for explaining a positional relation between the fine-pitch wiring patterns 9 to be transferred onto a resist film on a semiconductor substrate and the photomask 11 on which the hole patterns 12 shown in FIG. 3 are arranged. As explained in the comparative example, dimensions of the photomask are values converted into dimensions when the photomask is transferred onto the resist film on the semiconductor substrate. Therefore, for convenience of explanation, a positional relation between fine-pitch wirings to be transferred onto the resist film on the semiconductor substrate and mask patterns arrayed on the photomask for contact hole formation is discussed below.

The wiring patterns 9 are transferred onto the resist film by applying the resist film on the semiconductor substrate after contact hole formation and performing exposure with an exposing apparatus having the numerical aperture NA=1.3 using a photomask for wiring formation on which fine-pitch wiring patterns are arrayed.

In the method of exposing contact holes according to this embodiment, even when a numerical aperture of an exposing apparatus used for contact hole formation is lower than a numerical aperture of an exposing apparatus used for wiring pattern formation, it is necessary to densely form fine contact holes having high resolution. Therefore, a certain restriction described below is applied between the pitch Pₗᵢₙₑ among the wiring patterns 9 and the pitch Pₕₒₗₑ among the hole patterns 12 and the assist patterns 13.

When a pitch among the wiring patterns 9 is represented as Pₗᵢₙₑ and a pitch among the hole patterns 12 and the assist patterns 13 is represented as Pₕₒₗₑ, a photomask only has to be manufactured such that the following relational expression holds.

m×Pₗᵢₙₑ=n×Pₕₒₗₑ (m and n are integers and m>n) (2)

Exposure only has to be performed to align center lines of the wiring patterns 9 and the hole patterns 12. In FIG. 5, the relational expression (2) is satisfied when m=4, n=3,Pₗᵢₙₑ=42 nm, and Pₕₒₗₑ=56 nm.

Therefore, a photomask only has to be designed and manufactured such that the pitch Pₕₒₗₑ among the hole patterns 12 and the assist patterns 13 satisfies a relation Pₕₒₗₑ=(4/3)×Pₗᵢₙₑ with respect to wiring patterns having the fine pitch Pₗᵢₙₑ determined by the photolithography resolution technology.

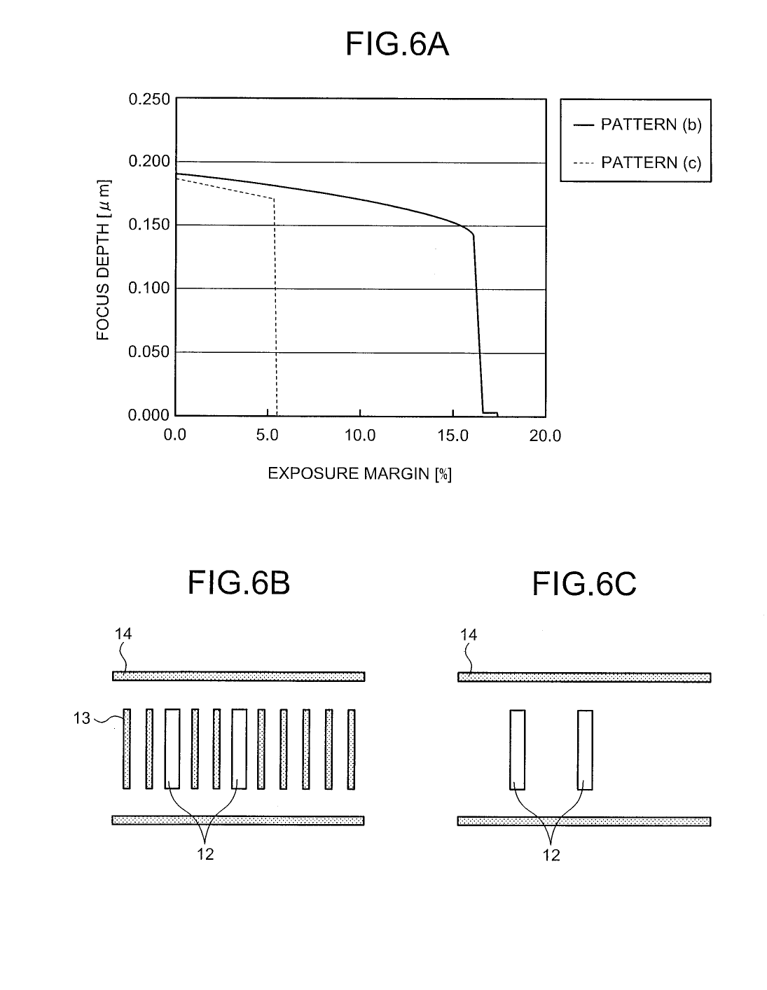

An exposure margin of patterns formed by applying the method described above is shown in FIG. 6A. In FIG. 6A, a relation between focus depth [μm] and an exposure margin [%] at the time when the hole patterns 12 and the assist patterns 13 satisfy the relation Pₕₒₗₑ=(4/3)×Pₗᵢₙₑ is indicated by a solid line. Photomask patterns corresponding to the solid line is schematically shown in FIG. 6B. Dimensions of the hole patterns 12, the assist patterns 13, the assist patterns 14, and the like are identical with the values explained with reference to FIG. 3. For comparison, a relation between focus depth [μm] and an exposure margin [%] at the time when the assist patterns 13 are not arranged and only the hole patterns 12 are arranged is indicated by a dotted line.

FIG. 6A is a graph of a simulation result obtained when the numerical aperture NA is 1.0, an illumination shape is fan-shaped four-eye illumination, the opening position σ is 0.8, and polarization is tangential polarization. As comparison of the solid line and the dotted line shown in FIG. 6A clarifies, it is seen that the exposure margin is substantially improved compared with that before the application of this embodiment (FIG. 6C) by arranging the assist patterns 13 among the hole patterns 12 at an equal pitch (FIG. 6B). In other words, it is possible to densely form contact holes having small dimensional fluctuation and small width.

In the past, for example, in the isolated pattern arrangement shown in FIG. 9, a positional relation between the pitch Pₗᵢₙₑ among the wiring patterns and the pitch Pₕₒₗₑ among the hole patterns and the assist patterns does not satisfy the relational expression (2). On the other hand, in this embodiment, because the relational expression (2) is satisfied, it is possible to reduce the number of the assist patterns arranged among the hole patterns without decreasing the exposure margin. Further, even by an exposing apparatus having a numerical aperture lower than that of the exposing apparatus used for formation of the wiring patterns, because the pitch Pₕₒₗₑ among the hole patterns and the assist patterns is increased, contact hole formation with high resolution is possible.

As described above in detail, with the method of manufacturing a semiconductor device, i.e., the method of exposing fine contact holes according to this embodiment, when the pitch among the fine-pitch wirings is represented as Pₗᵢₙₑ and the pitch among the hole patterns and the assist patterns is represented as Pₕₒₗₑ, the hole patterns and the assist patterns are arranged such that the relational expression (2) m×Pₗᵢₙₑ=n×Pₕₒₗₑ (m and n are integers and m>n) holds. Exposure is performed to align the center lines of the fine-pitch wirings and the hole patterns. Therefore, even when exposure of contact holes is performed by an exposing apparatus having a numerical aperture lower than that of the exposing apparatus for wiring formation, it is possible to form dense contact holes having high resolution. Therefore, it is possible to reduce a region necessary for wiring drawing-out patterns compared with that in the past and reduce a chip area.

An exposure margin of the hole patterns is improved as mask dimensions of the assist patterns are larger. On the other hand, likelihood of transfer of the assist patterns onto the resist film increases. Therefore, the mask dimensions of the assist patterns are adjusted according to an exposure condition of the hole patterns. For example, when resist dimensions of the hole patterns are increased, the mask dimensions of the assist patterns only have to be reduced.

In this embodiment, a method of exposing contact holes formed in the sense-amplifier wiring drawing-out region of the NAND flash memory is explained. However, the present invention is not limited to this. The present invention can also be applied when contacts for electrically connecting different wiring layers are formed in various semiconductor devices. In particular, the present invention is effective when contact holes are formed by an exposing apparatus having a numerical aperture smaller than that used for wiring pattern formation.

In this embodiment, the values satisfying the relational expression (2) are explained as m=4, n=3,Pₗᵢₙₑ=42 nm, and Pₕₒₗₑ=56 nm. However, the present invention is not limited to this. For example, a combination of values such as m=6, n=4, Pₗᵢₙₑ=42 nm, and Pₕₒₗₑ=63 nm can be used. In this case, the pitch Pₕₒₗₑ among the hole patterns and the assist patterns is further increased. Therefore, it is easier to form the patterns. In other words, an appropriate combination of values only has to be selected with respect to the pitch Pₗᵢₙₑ among the wiring patterns by taking into account factors such as performance of an exposing apparatus used for contact hole formation and size allowed for the wiring drawing-out region.

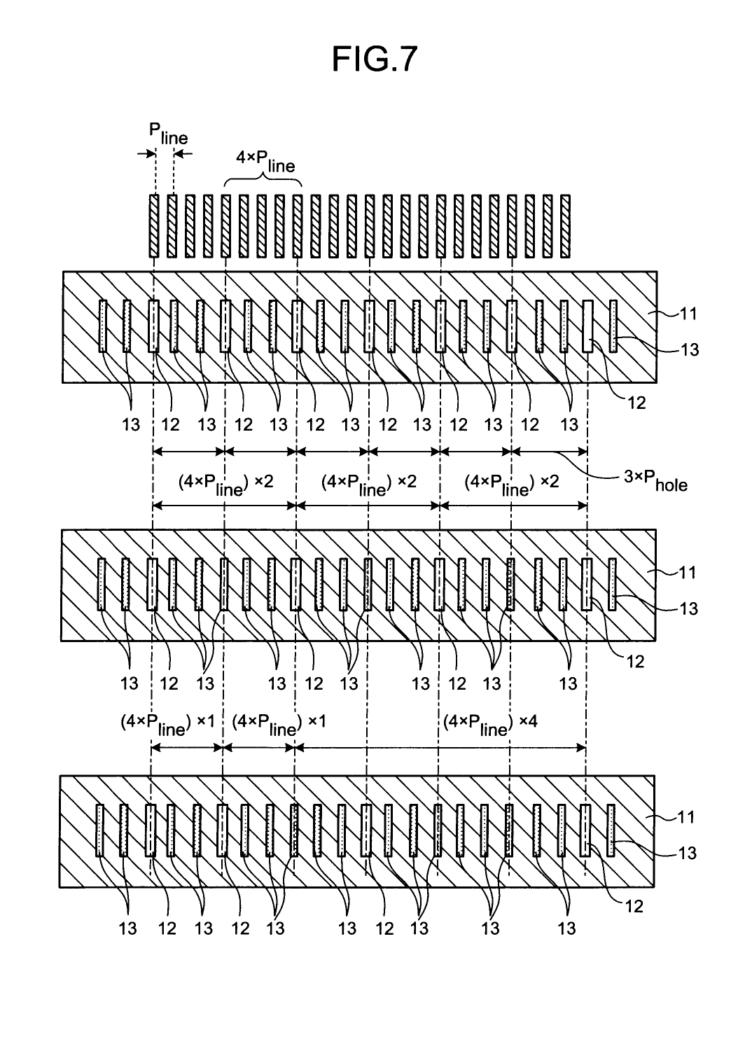

A method of manufacturing a semiconductor device according to a second embodiment of the present invention is explained with reference to FIG. 7. Components substantially the same as those in the first embodiment are denoted by the same reference numerals and signs and redundant explanation of the components is omitted.

In the second embodiment, variations of a contact hole arrangement obtained by using the method of exposing fine contact holes according to the first embodiment are explained with reference to FIG. 7. FIG. 7 are plan views of variations of the contact hole arrangement according to this embodiment.

In the photomask 11 shown in the upper of FIG. 7, as in the first embodiment, the hole patterns 12 are formed at a pitch three times as large as the pitch Pₕₒₗₑ among the hole patterns 12 and the assist patterns 13. In other words, the center lines of the hole patterns 12 and the center lines of the wiring patterns 9 overlap in positions where the hole patterns 12 are formed. In the positions, any one of the assist patterns 13 and the hole patterns 12 can be arranged. Therefore, variations of an arrangement are possible as described below.

As an arrangement rule for contact holes, the contact holes are arranged at pitches integer times as large as a value obtained by multiplying the wiring pitch Pₗᵢₙₑ with an integer m. In this embodiment, because m is 4 as in the first embodiment, it is possible to arrange the contact holes at a pitch integer times as large as (4×Pₕₒₗₑ). However, the present invention is not limited to this. A minimum value of a pitch at which the contact holes can be arranged is decided according to a value of the integer m that satisfies the relational expression (2).

For example, as shown in the middle of FIG. 7, with a pitch among the hole patterns 12 set as (4×Pₗᵢₙₑ)×2, (4×Pₗᵢₙₑ)×2, (4×Pₗᵢₙₑ)×2, . . . , contact holes can be formed at a pitch twice as large as the hole pattern pitch shown in the upper of FIG. 7. Alternatively, as shown in the lower of FIG. 7, the pitches among the hole patterns 12 can be set as (4×Pₗᵢₙₑ)×1, (4×Pₗᵢₙₑ)×1, (4×Pₗᵢₙₑ)×4, . . . . In other words, the hole patterns 12 do not always have to be arrayed at an equal pitch.

If the variations of the contact hole arrangement described above are used, it is easy to apply the present invention to various wiring drawing-out patterns. For example, it is possible to increase a degree of freedom of wiring drawing-around and facilitate layout of a peripheral circuit by expanding or reducing intervals among the contact holes.

Inventions at various stages are included in the first embodiment and the second embodiment. Various inventions can be extracted according to appropriate combinations of a plurality of elements disclosed herein. For example, even if several elements are deleted from all the elements disclosed in the embodiments, when at least one of the problems explained above can be solved and at least one of the effects explained above can be obtained, the elements remaining after the elements are deleted can be extracted as an invention.

According to the present invention, it is possible to provide a method of manufacturing a semiconductor device that can reduce a wiring drawing-out pattern region.

What is claimed is:

1. A method of manufacturing a semiconductor device for transferring a pattern formed on a photomask onto a resist film on a semiconductor substrate using an exposing apparatus, the method comprising:
performing exposure using a first photomask having a pattern line in which hole patterns and assist patterns not transferred onto the semiconductor substrate, surrounded by a light shielding section or a semitransparent film, are arrayed at an equal pitch on the mask, the pitch being converted a first pitch on the substrate when the mask patterns are transferred on the substrate; and
performing exposure using a second photomask having a pattern line in which wiring patterns surrounded by a light shielding section or a semitransparent film are arrayed at an equal pitch on the mask, the pitch being converted a second pitch on the substrate when the mask patterns are transferred on the substrate, wherein
a value obtained by multiplying the second pitch with an integer m is equal to a value obtained by multiplying the first pitch with an integer n, and
the integer m is larger than the integer n.

2. The method according to claim 1, wherein a numerical aperture of the exposing apparatus in the performing exposure using the first photomask is smaller than a numerical aperture of the exposing apparatus in the performing exposure using the second photomask.

3. The method according to claim 1, wherein the hole patterns can be arranged at pitches integer times as large as the value obtained by multiplying the second pitch with the integer m.

4. The method according to claim 3, wherein the hole patterns are not arrayed at an equal pitch.

5. The method according to claim 1, wherein the second pitch is a minimum pitch that is resolvable by the exposing apparatus.

6. The method according to claim 1, wherein the exposure is performed to align center lines of the wiring patterns and center lines of the hole patterns.

7. The method according to claim 1, wherein
two of the assist patterns are arranged between the hole patterns, and
a value obtained by multiplying the first pitch with three is equal to a value obtained by multiplying the second pitch with four.

8. The method according to claim 1, wherein
two of the assist patterns are arranged between the hole patterns, and
a value obtained by multiplying the first pitch with four is equal to a value obtained by multiplying the second pitch with six.

9. The method according to claim 1, wherein a pair of the assist patterns are arranged a predetermined space apart from each other in a direction orthogonal to an array direction of the hole patterns and the assist patterns to hold the hole patterns and the assist patterns.

10. The method according to claim 1, wherein an illumination shape of the exposing apparatus is a fan-shaped two-eye illumination shape or a fan-shaped four-eye illumination shape.

11. The method according to claim 1, wherein a mask dimension of the assist patterns is adjusted according to an exposure condition for the hole patterns.

12. The method according to claim 1, wherein
the wiring patterns are applied to formation of sense-amplifier-region wiring drawing-out patterns in a sense amplifier region of a NAND flash memory,
the hole patterns are applied to formation of contact holes that electrically connect the sense-amplifier-region wiring drawing-out patterns to drawing-out wirings in a lower layer, and
the second pitch is equal to a pitch among gate wirings in a memory cell array of the NAND flash memory.
